(19) United States
(12) Patent Application Publication
(10) Pub. No.: US 2012/0087098 A1
(43) Pub. Date: Apr. 12, 2012

(54) PACKAGE SUBSTRATE

(75) Inventors: Dong Uk LEE, Chungcheoungbuk-do (KR); Seung Hyun NOH, Daejeon (KR)

(73) Assignee: SAMSUNG ELECTRO-MECHANICS CO., LTD., Gyunggi-do (KR)

(21) Appl. No.: 13/252,717

(22) Filed: Oct. 4, 2011

(30) Foreign Application Priority Data
Oct. 6, 2010 (KR) 10-2010-0097343

(51) Int. Cl. H05K 7/00

(52) U.S. Cl. 361/767

(57) ABSTRACT

Disclosed herein is a package substrate, including: a printed circuit board having a connection terminal and a conductive adhesive layer formed thereon; components mounted in the connection terminal; wires coupled to the components; a wall printed circuit board coupled to the conductive adhesive layer and configured to cover the components; and a metal cap coupled to an upper end of the wall printed circuit board to cover the components, thereby ensuring firmness and reliability despite external impact.

### CROSS REFERENCE TO RELATED APPLICATION

This application claims the benefit of Korean Patent Application No. 10-2010-0097343, filed on Oct. 6, 2010, entitled “Package Substrate”, which is hereby incorporated by reference in its entirety into this application.

### BACKGROUND OF THE INVENTION

1. Technical Field

The present invention relates to a package substrate.

2. Description of the Related Art

Microphone packages according to the prior art may malfunction and noise occurs due to electronic waves generated from other peripheral electronic components. Subsequently, in order to resolve the above problems, after the components have been mounted in a substrate, it is sealed with metal materials, thereby blocking the electronic waves.

However, in the prior microphone packages, defects are caused due to the lack of adhesion between a cap made of metal material and a printed circuit board.

More particularly, FIG. 1 is a cross sectional view schematically showing a package substrate according to the prior art. As shown in the drawing, the package substrate 100 includes a printed circuit board 110, components 120, wires 130, and a metal cap 140.

Further, the printed circuit board 110 includes a baseboard 111 and a connection terminal 112 coupled to the baseboard 111. Furthermore, one or more components 120 are mounted in the connection terminal 112, and the components 120 are wire-bonded to the connection terminal through the wires 130. In addition, the metal cap 140 is coupled to the printed circuit board 110 such that the components are covered.

The package substrate according to the prior art that is implemented as described above has problems in that the adhesion between the metal cap 140 and the printed circuit board 110 is insufficient, and the metal cap 140 is implemented to incur high-weight, but the metal cap 140 and the printed circuit board 110 are separated from each other when impact is applied thereto from the outside.

### SUMMARY OF THE INVENTION

The present invention has been made in an effort to provide a package substrate in which a wall printed circuit board (Wall PCB) is coupled to a printed circuit board and a metal cap is coupled to the upper end of the wall printed circuit board, thereby ensuring firmness and reliability despite external impact.

A package substrate according to a preferred embodiment of the present invention includes: a printed circuit board having a connection terminal and a conductive adhesive layer formed thereon; components mounted in the connection terminal; wires coupled to the components; a wall printed circuit board coupled to the conductive adhesive layer and configured to cover the components; and a metal cap coupled to a upper end of the wall printed circuit board to cover the components.

The printed circuit board includes a connection terminal for mounting the components and a connection terminal for wire bonding, and a conductive adhesive layer is formed on a border part thereof.

The printed circuit board further includes a connection terminal for being mounted on a motherboard.

The wall printed circuit board is formed in a shape of a square frame.

The metal cap is formed in a shape of a plate.

The printed circuit board is a printed circuit board for a microphone, and the component is a microphone component.

### BRIEF DESCRIPTION OF THE DRAWINGS

FIG. 1 is a cross sectional view schematically showing a package substrate according to the prior art;

FIG. 2 is a cross sectional view schematically showing a package substrate according to the present invention; and

FIG. 3 is a partial plan view of the package substrate shown in FIG. 2.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted.

Hereinafter, preferred embodiments of a package substrate according to the present invention will be described in detail with reference to the accompanying drawings.

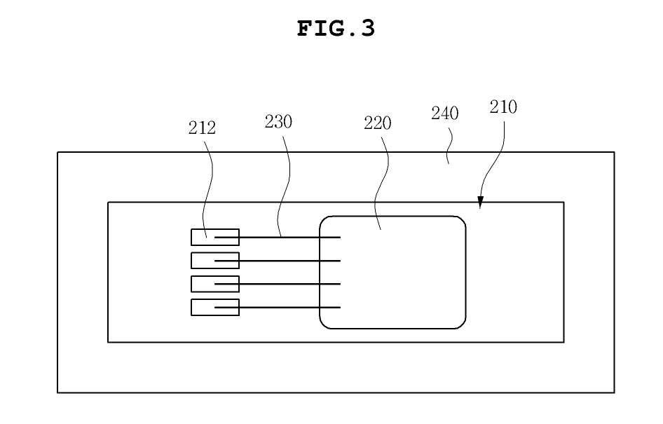

FIG. 2 is a cross sectional view schematically showing a package substrate according to the present invention and FIG. 3 is a partial plan view in which a metal cap is removed from the package substrate shown in FIG. 2. As shown in the drawing, the package substrate 200 includes a printed circuit board 210, components 220, wires 230, a wall printed circuit board 240 and a metal cap 250.

The printed circuit board 210 includes a base board 211, a connection terminal 212, and a conductive adhesive part 213.

Furthermore, one or more components 220 are mounted in the connection terminal 212, and the components 220 are wire-bonded to the connection terminal of the printed circuit board by the wires 230. Furthermore, the printed circuit board further includes a connection terminal in other to be mounted on a motherboard.

Furthermore, the wall printed circuit board 240 is formed in the shape of a square frame as shown in FIG. 3, and is adhered and fixed to the conductive adhesive part 213 of the printed circuit board.

Furthermore, the metal cap 250 is implemented in the shape of a plate, and is coupled to the upper end of the wall printed circuit board 240 to cover the components.

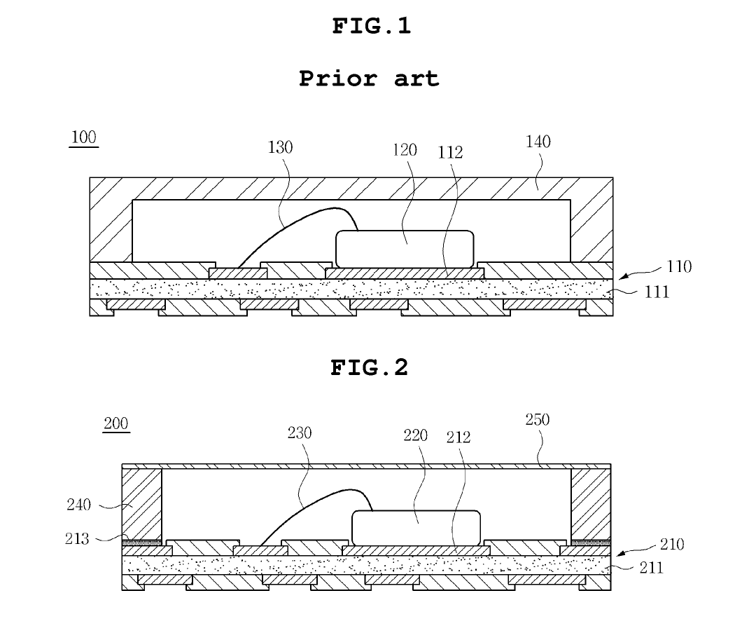

Since the package substrate 200 according to the present invention is implemented as described above, the adhesion between the printed circuit board 210 and the wall printed circuit board 240 is improved by the conductive adhesive part 213 and since the metal cap 250 is formed in the shape of a plate, and thus has less weight compared to the metal cap 140 of the package substrate according to the prior art shown in FIG. 1, firmness and reliability are improved against external impact.

Furthermore, a method for manufacturing the package substrate according to the present invention is described below.

A printed circuit board and a wall printed circuit board are respectively prepared, and components are mounted in the printed circuit board and then are wire-bonded thereto. The wall printed circuit board is coupled to the conductive adhesive part of the printed circuit board, and a metal cap is coupled to the upper end of the wall printed circuit board.

Furthermore, the package substrate according to the present invention may be implemented as a package for a microphone. In this case, the printed circuit board is a printed circuit board for the microphone, and the component is a microphone component. Furthermore, in this case, the wall printed circuit board is preferably formed to have a height of 700 μm.

According to the present invention, there is an advantage of providing a package substrate in which a wall printed circuit board (Wall PCB) is coupled to a printed circuit board and a metal cap is coupled to the upper end of the wall printed circuit board, thereby ensuring firmness and reliability despite external impact.

Although the preferred embodiments of the present invention have been disclosed for illustrative purposes, they are for specifically explaining the present invention and thus a package substrate according to the present invention is not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A package substrate, comprising:
a printed circuit board having a connection terminal and a conductive adhesive layer formed thereon;
components mounted in the connection terminal;
wires coupled to the components;
a wall printed circuit board coupled to the conductive adhesive layer and configured to cover the components; and
a metal cap coupled to an upper end of the wall printed circuit board to cover the components.

2. The package substrate as set forth in claim 1, wherein the printed circuit board includes a connection terminal for mounting the components and a connection terminal for wire bonding, and a conductive adhesive layer is formed on a border part thereof.

3. The package substrate as set forth in claim 2, wherein the printed circuit board further includes a connection terminal for being mounted on a motherboard.

4. The package substrate as set forth in claim 1, wherein the wall printed circuit board is formed in a shape of a square frame.

5. The package substrate as set forth in claim 1, wherein the metal cap is formed in a shape of a plate.

6. The package substrate as set forth in claim 1, wherein the printed circuit board is a printed circuit board for a microphone, and the component is a microphone component.
